(19) United States
(12) Patent Application Publication
(10) Pub. No.: US 2026/0239773 A1
(43) Pub. Date: Aug. 13, 2026

(54) A METHOD FOR FORMING AN ELECTRICAL CONNECTION ON A SURFACE OF A SUBSTRATE

(71) Applicant: SUNDRIVE SOLAR PTY LTD, Kurnell (AU)

(72) Inventors: Jack Killian Colwell, Kurnell (AU); Alison Joan Lennon, Kurnell (AU); Daniel Chen, Kurnell (AU); Chris Huang, Kurnell (AU); Vincent Akira Allen, Kurnell (AU)

(21) Appl. No.: 19/139,750

(22) PCT Filed: Dec. 15, 2023
(86) PCT No.: PCT/AU2023/051306

§ 371 Date: Jun. 16, 2025

(30) Foreign Application Priority Data
Dec. 16, 2022 (AU) 2022903881

(51) Int. Cl. H10F 77/00; H10F 71/00

(52) U.S. Cl. CPC H10F 77/935; H10F 71/137

(57) ABSTRACT

Disclosed is a device comprising a substrate and at least one metallic contact within a contact area. The at least one metallic contact may comprise a structure having first regions of a metallic material which are spaced apart by second regions in which the metallic material is not positioned. The first regions may be spaced apart by the second regions in two dimensions. The device may further comprise at least one electrically conductive wire being coupled to the metallic material using a coupling material. At least some of the coupling material may also be positioned over the substrate at the second regions within the at least one metal contact area within the contact area. Also disclosed is a method of forming the device.

### FIELD OF THE INVENTION

The present invention relates generally to a method for forming an electrical connection on a surface of a substrate and relates in particular, though not exclusively, to a method for forming an electrical connection on a solar cell to enable electrical interconnection to an adjacent solar cell within a string of solar cells.

### BACKGROUND OF THE INVENTION

Most solar photovoltaic (PV) modules comprise one or more strings of series connected solar cells encapsulated in a polymer with a glass front sheet and a glass or polymer back sheet. To enable the interconnection of the individual solar cells within the strings, each of the solar cells typically has one or more busbars to which solder-coated electrical wires can be affixed. The busbars collect the photo-generated current from a plurality of thin metal lines, commonly referred to as “fingers”, and enable the collected current to flow from one polarity of the solar cell to another polarity on an adjacent solar cell via the electrical wires. The arrangement of fingers and perpendicularly oriented busbars on a surface of the solar cell is commonly referred to as a “contact grid”.

For the most commonly manufactured two-side contacted solar cells, the semiconducting regions having a first polarity are on a front surface and the semiconducting regions having a second polarity are back surface of the solar cell. Consequently, the interconnection electrical wire must ‘bend’ between the back of one solar cell to the front surface of the adjacent cell.

However, for back contacted solar cells, each solar cell has p-type and n-type contact regions on the back surface. This means that the interconnection electrical wire does not need to be extended from the back to the front of adjacent solar cells. Back contacted solar cells eliminate front surface shading of the solar cell as all the metal contact regions are on the back of the solar cell, however this benefit is at the expense of greater cost of manufacturing.

For both two-side contacted solar cells and back contacted solar cells, automatic stringing machines exist which extend the interconnection electrical wires across the busbars of the solar cells and form a bond between the interconnection electrical wire and busbar on the solar cell. This process requires alignment between the solar cells and the interconnection electrical wires, which are typically wound on a spool, gradually unwound and fed across the solar cell for the soldering process. The bonding is achieved by either the application of heat or infrared (IR) radiation, both of which soften a solder coating on the interconnection electrical wire so that it flows over the busbar regions and solidifies as a bond on cooling.

In order to reduce the amount of metal required for each solar cell to be interconnected to an adjacent solar cell, it is known to replace the fully metallised busbars with a series of contact pads which are connected to each other by thinner metal busbars. FIG. 1 shows a corner of a solar cell 100 with a plurality of thin metal fingers 105 and perpendicular busbar structures 110. The busbar structures comprised in this example contain sections of parallel linear regions with contact pads 115 spaced at intervals along the length of the busbar structure.

Interconnection of solar cells with this grid pattern requires thermal or infrared (IR) soldering of interconnection electrical wires to the contact pads 115. On cooling, the contact pads of the solar cell are bonded to the interconnection electrical wires via a solder bond. This type of contact grid pattern can reduce the amount of metal required on the solar cell whilst continuing to provide sufficient bonding of the interconnection electrical wire to the solar cell and a low resistance current path for the photogenerated current to flow from one cell to the adjacent solar cell in a string of solar cells.

The reduction of metal achieved with this contact grid is particularly advantageous because most solar cells use silver for their metal contact regions and silver is the costliest material after silicon in solar cells. The area of these contact pads is typically in the order of 1-2 mm² with slightly larger pads frequently used at the edges of the cell. Although it is desirable from a metal cost perspective to make these solder pads as small as possible, their width needs to remain sufficient large for the alignment tolerance margin of automatic solar cell stringing machines routinely used in PV module manufacturing. The contact pads also need to allow for sufficient contact area to allow the melted solder to flow over the solar cell pad area to ensure adequate bonded adhesion between the interconnection wire and the solar cell.

A reduced mass of metal directly reduces the cost of the PV module. An even greater reduction of cost can be obtained if the silver can be replaced by a metal such as copper, which is more electrically conductive than the silver pastes used to form a silver grid but much cheaper. Whilst plating with copper has been trialed for use as a replacement metal for silver, poor adhesion of the metallic fingers and busbar structures to the surfaces of the solar cell has made it very difficult to interconnect solar cells in the abovementioned manner.

There is a need for technological advancement.

### SUMMARY OF THE INVENTION

In a first aspect of the present invention there is provided a method of forming an electrical connection on a surface of a substrate that forms part of a solar cell, the method comprising:
providing the substrate and a material for forming at least one metallic contact on the surface of the substrate;
forming the at least one metallic contact on the surface of the substrate, comprising selecting at least one contact area on the surface of the substrate and forming a structure of a polycrystalline metallic material within the at least one contact area, the structure having first regions of a polycrystalline metallic material which are spaced apart by second regions in which the substrate is exposed, wherein the first regions are spaced apart by the second regions in two dimensions;
providing at least one electrically conductive wire and a coupling material; and
coupling the at least one electrically conductive wire to the formed at least one metallic contact using the coupling material in a manner such that at least some of the coupling material is also positioned over the substrate at the second regions within the at least one metal contact area within the contact area.

Throughout the specification the term “electrical wire” is used for an elongated electrical conductor having any cross-sectional shape such as, but not limited to, round, rounded, rectangular or triangular. Further, the electrical wire may also have a cross-sectional shape that changes along a length portion of the electrical wire, such as from generally rectangular cross-sectional shape to round cross-sectional shape.

The material may be a polycrystalline material. A coefficient of thermal expansion of the material may be ≥3 times that of the substrate. The material may have an elastic modulus >50 GPa. The material may have a yield stress >25 MPa. The material may be formed from substantially a single chemical element. The material may be a single material.

The coupling material may be in direct contact with the substrate in at least some of the second regions. Some of the coupling material may also be positioned over, and spaced apart from the substrate at least some of the second regions and may not be in direct contact with the substrate at each second region.

The coupling material may be a solder material and coupling the at least one electrically conductive wire to the formed at least one metallic contact may comprise soldering the at least one electrically conductive wire to the formed at least one metallic contact. Soldering the at least one electrically conductive wire to the formed at least one metallic material may for example comprise the application of heat or the application of infrared (IR) radiation.

Alternatively, the coupling material may be a conductive adhesive material and the step of coupling the at least one electrically conductive wire to the formed at least one metallic contact may comprise adhering the at least one electrically conductive wire to the formed at least one metallic contact.

In one embodiment the first regions of the metallic material are joined, such as integrally formed. For example, the first regions of the metallic material may comprise one or more lines or the like which may or may not cross other lines. The first regions of the metallic material may form a pattern or grid-like structure which may be a periodic structure. The first regions of the metallic material may form an array within the at least one contact area.

The at least one metallic contact may also comprise at least some first regions of the metallic material which are separate from each other and are not in direct contact with other first regions of the metallic material. The first regions of the metallic material may include a pattern of islands such as dots which may form a periodic structure and may form an array.

The at least one metallic contact may have a shortest extension in a plane of the metallic contact of less than 2 mm, less than 1 mm, less than 0.5 mm, or even less than 0.2 mm. The first regions of metallic material may have a shortest extension in a plane of the metallic contact of less than 100 μm, less than 50 μm, less than 20 μm or even less than 15 μm. The second regions may have a shortest extension in a plane of the metallic contact of less than 500 μm, less than 100 μm, less than 50 μm or even less than 25 μm.

The at least one electrically conductive wire may be coated with a solder material. Alternatively, the method may comprise the step of providing a solder material separate from the at least one electrically conductive wire and soldering the at least one electrically conductive wire to the formed metallic contact using the solder material.

The metallic material may be any suitable material (such as Cu, Ni, SN or Ag), but in one specific embodiment the metallic material comprises Cu or a combination of another metal, such as Ni, with Cu. In the latter case, the Ni and Cu can be formed in separate layers.

The at least one electrically conductive wire may be of any suitable form and in one embodiment has a generally circular or rectangular cross-sectional shape.

The substrate may comprise a semiconductor material such as silicon. In one embodiment the substrate forms a part of a solar cell and the metallic contact is an electrical contact on a surface of the solar cell.

The inventors have observed that the adhesion of the metallic contact to the substrate can be improved if the metallic contact comprises a structure of first regions of metallic material spaced apart by the second regions in two dimensions and the coupling or solder material couples or bonds the electrically conductive wire to the metallic material and also flows over at least over the second regions (and may or may not be in direct contact with the substrate material in the second regions). Consequently, embodiments of the present invention provide the advantage of improved adhesion of the metallic contacts, which may for example be portions of busbars on solar cell surfaces. The first regions of metallic material may also act as “hooks” for the coupling material (such as solidified solder), which further increases adhesion.

In addition, because the first regions of the metallic material are spaced apart by second regions, the metallic contact requires a reduced amount of metallic material, such as copper.

The at least one metallic contact may be one of a plurality of metallic contacts and the method may comprise forming a plurality of the metallic contacts on the surface of the substrate. The metallic contacts may form a portion of a busbar on a surface of a device, such as a solar cell.

The substrate may be one of a plurality of substrates which may comprise solar cells.

The solar cells may be within or form part of a solar cell module.

The at least one electrically conductive wire may be used to interconnect adjacent solar cells by connecting one polarity of one of the solar cells with an opposite polarity of an adjacent one of the solar cells. The solar cells may be arranged for two-side contacting or only back contacting. The adjacent solar cells may be interconnected to form a solar cell module.

In a second aspect of the present invention there is provided a device having an electrical connection formed by the method in accordance with the first aspect of the present invention.

In a third aspect of the present invention there is provided a device comprising:
a substrate that forms a part of a solar cell;
at least one metallic contact within a contact area, the at least one metallic contact comprising a structure having first regions of a polycrystalline metallic material which are spaced apart by second regions in which the polycrystalline metallic material is not positioned, wherein the first regions are spaced apart by the second regions in two dimensions; and
at least one electrically conductive wire coupled to the polycrystalline metallic material with a coupling material;
wherein at least some of the coupling material is also positioned over the substrate at the second regions within the at least one metal contact area.

The material may be a polycrystalline material. A coefficient of thermal expansion of the material may be ≥3 times that of the substrate. The material may have an elastic modulus >50 GPa. The material may have a yield stress >25 MPa. The material may be a single material. The material may be formed from substantially a single chemical element.

Some of the coupling material may be in direct contact with the substrate in at least some of the second regions. The coupling material may also be positioned over, and spaced apart from the substrate at at least some of the second regions without coupling material being in direct contact with the substrate at each second region.

The at least one metallic contact may have a shortest dimension in a plane of the metallic contact of less than 2 mm, less than 1 mm, less than 0.5 mm, or even less than 0.2 mm.

Further, the first regions of the metallic material may have a shortest dimension in a plane of the at least one metallic contact of less than 100 μm, less than 50 μm, less than 20 μm or even less than 15 μm.

The second regions may have a shortest dimension in a plane of the at least one metallic contact of less than 500 μm, less than 100 μm, less than 50 μm or even less than 25 μm.

The device may be, or may comprise, a solar cell. The coupling material may be a solder material or an electrically conductive adhesive.

The invention will be more fully understood from the following description of specific embodiments of the invention. The description is provided with reference to the accompanying drawings.

### BRIEF DESCRIPTION OF THE DRAWINGS

FIG. 1 is a schematic diagram of a corner of a solar cell with a metal contact grid comprising an array of metal fingers and busbar structures with a plurality of contact pads (prior art);

FIGS. 2A and 2B show fully metallised contact pads (prior art);

FIG. 2C shows an example of a partially metallised contact pad comprising a pattern of metallic material in accordance with an embodiment of the present invention;

FIGS. 3A, 3B and 3C are flow charts illustrating methods in accordance with embodiments of the present invention;

FIG. 4 is a scanning electron microscope image showing a cross-section of a plated copper segment in accordance with an embodiment of the present invention;

FIG. 5 is a schematic diagram illustrating a pattern of interconnected spaced apart metallic regions forming a pattern in accordance with an embodiment of the present invention;

FIG. 6A is schematic cross-sectional illustration of a fully metallised contact pad;

FIG. 6B is schematic cross-sectional illustration showing a series of metallic regions of a patterned contact pad in accordance with an embodiment of the present invention;

FIG. 7 is a table which compares measured busbar pull force and contact areas for solar cell interconnection wire structures formed with solid area contact pads and patterned contact pads in accordance with an embodiment of the present invention;

FIG. 8 is a digital photo showing that a fragment of silicon has been broken and pulled from the solar cell with contact pads formed using the pattern shown in FIG. 5 during a pull force measurement; and

FIG. 9a-9h shows pattern arrangements for patterned contact pads in accordance with embodiments of the present invention.

FIG. 10a-10h shows the contact pads of FIG. 9a-9h with various busbar structures.

### DETAILED DESCRIPTION OF EMBODIMENTS

Embodiments of the present invention relate to the formation of metallic contacts on a substrate, such as on one or more solar cells, which are electrically interconnected into a string of cells which can be laminated into a solar photovoltaic (PV) module or panel. The one or more solar cells may be connected to form a solar cell module.

Usually, the busbars are oriented perpendicular to the fingers within the contact grid, however this is not strictly required and other arrangements of fingers and collecting busbars (e.g., curved metal structures for applications on non-planar surfaces) can be used.

Throughout the description, the term “contact grid” is used to refer to a plurality of thin metal fingers and a plurality of busbar structures which are in electrical contact with the solar cells.

Electrical current flows from the solar cell into the metal fingers and then into the connecting busbar structures. Interconnection electrical wires are bonded to the busbar structures and transfer the current from the busbar structures to an adjacent solar cell in the interconnected string of solar cells. An interconnection electrical wire may for example have a circular, triangular or rectangular cross-sectional shape. When the interconnection electrical wire has a rectangular cross-sectional shape then it is often referred to as a ‘ribbon’ due to its flat shape. The shape of the interconnection wire can change along a string of solar cells. For example, round wires can be used for the front surface of solar cells and wires with a rectangular cross-sectional shape on the back surface. This arrangement is advantageous because it maximises the optical performance of a PV module due to the light re-directing properties of round wires, whilst reducing the amount of encapsulant required due to the lower height of wires with a rectangular cross-sectional shape.

Historically busbar structures were fully metallised linear structures which would extent along the length of the solar cell in a so-called H-bar pattern. This arrangement ensured a large contact area between the solar cell and the interconnection electrical wire for the formation of a solder bond on interconnection. It is now more common for busbar structures to comprise a series of connected contact pads and bonding with the interconnection wires occurs primarily at the contact pads, instead of along the entire length of the busbar. This arrangement is typically adopted to reduce the amount of metal required for the busbar structures on the solar cells.

Embodiments of the present invention provide a method of forming metallic contacts on the solar cell which comprise, within a contact area, first regions of a metallic material which are spaced apart by second regions and form a two-dimensional structure, such as a pattern or grid within the contact area (which may have a shortest extension in a plane of the metallic contact of less than 2 mm, less than 1 mm, less than 0.5 mm or less than 0.2 mm or another suitable extension). The inventors have observed that such contact pads increase the adhesion of busbar structures to interconnection electrical wires over that routinely achieved with solid metallised contact pads (prior art) of similar dimensions. The method also reduces the mass of metal required to form the contact grid on the solar cell.

One embodiment of the present invention uses a low-cost metal such as copper, though other conductive materials may also be used in alternative embodiments. The use of copper rather than silver, which is commonly used to form the contact grids of solar cells, can reduce the cost of manufacturing PV modules due to the lower cost of copper compared with silver.

Copper can be electroplated directly onto a surface of the solar cell resulting in metal structures which have a conductivity approaching that of pure copper, which is significantly higher than the conductivity of screen-printed silver pastes, especially the pastes which need to be cured at low temperatures. This means that for forming a given contact grid pattern, the mass of copper required can be lower than the mass required for a screen-printed silver contact grid.

Although the present invention is described with reference to silicon-based solar cells and their interconnections, it should be clear to a person skilled in the art that the method could also be applied to other solar cells, including thin film solar cells, such as solar cells comprising cadmium telluride (CdTe), copper indium gallium selenide (CIGS), perovskite structures and various tandem and multijunction devices.

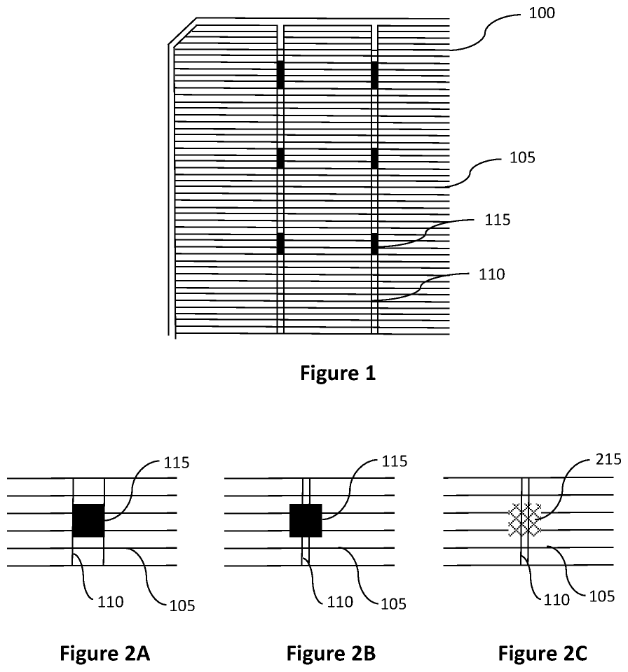

FIG. 1 schematically illustrates a corner of a commonly used contact grid for a silicon-based solar cell 100 in accordance with the prior art. The contact grid comprises an array of metal fingers 105 with a plurality of busbar structures 110 spaced across the solar cell 100.

Solid metal contact pads 115 are placed at regularly spaced intervals along the busbar structures 110. When the solar cell 100 is interconnected, photo-generated current is collected in the fingers and flows along the fingers to the nearest busbar structure 110. The current will then flow along the metal lines of the busbar structure 110 until it reaches the nearest contact pad 115, from where it can flow into the interconnection wire and to the adjacent solar cell.

It is commonplace when using screen-printed silver for the contact grids of solar cells to limit the distance that current must travel along the metal fingers 105 before being collected in a busbar structure because this has the advantage of reducing the mass of silver paste that needs to be printed on the solar cell. The finger height, or more correctly, the cross-sectional area of fingers can be reduced as the maximum current that flows along a finger is less than it would be if the busbars were spaced further apart. This means for a solar cell fabricated on a 166 mm (M6) silicon wafer, the total number of busbar structures 110 can be as many as 9 or 12, or in some cases even more. For larger solar cells as many as 20 busbar structures may be employed in order to reduce the mass of silver required and hence the cost of the cell metallization.

When using electroplated copper in place of silver, it is not as critical to reduce the copper finger height. Consequently, a large number of busbar structures is not required for cost reduction purposes. However, spacing busbar structures more closely can reduce the magnitude of any stress which may be induced in the electroplated copper fingers. This can reduce the possibility that fingers may peel or lose adhesion after plating.

When copper is plated at room temperature, impurities and defects can be incorporated in the crystalline grains of the plated structures causing compressive stress. Faster plating can result in more incorporated impurities and crystal defects and hence increase the induced compressive stress. The energy associated with incorporated impurities/defects is typically dissipated in a self-annealing process which results in the growth of crystal grains and often a change in the dominant crystal structure. The grain growth process can increase tensile stress in the plated structure. Ideally the self-annealing process can counter or balance the compressive stress induced during deposition.

Thermal treatments of electroplated copper structures on solar cells can also introduce stress in the solar cell due to the different coefficients of thermal expansion (CTE) of the copper and the solar cell absorber (e.g., silicon). Polycrystalline copper has a CTE of 17×10⁻⁶ K⁻¹, which is ~6 times larger than the rigid silicon wafer (2.6-3.3×10⁻⁶ K⁻¹). Furthermore, the elastic modulus of polycrystalline copper can be as large as 100 GPa and its yield/tensile stress is typically >60 MPa. This means that, as the solar cell is rapidly heated and cooled during cell interconnection, stress can be induced in the copper electrode and the silicon wafer due to the greater expansion and contraction of the copper. This stress is not easily dissipated by plastic copper flow and consequently significant stress can also be induced in the silicon wafer of the solar cell.

In comparison, most industrially used silver pastes typically have CTE values of ~10×10⁻⁶ K⁻¹ (e.g., see: C. Kohn et al., Analyses of warpage effects induced by passivation and electrode coatings in silicon solar cells, 22^{nd} European Photovoltaic Solar Energy Conference, 2007), which is ~half that of copper. Additionally, the stress induced by the different rates of expansion and contraction of the silver solder pads relative to the silicon wafer is largely mitigated by the cured paste's low elastic moduli (e.g., 7-10 GPa as reported by X. Gesheng et al., Mechanical properties of cured isotropic conductive adhesive (ICA) under hygrothermal aging investigated by micro-indentation, International Journal of Solids and Structures, 122-123, 81-90, 2017) and a low yield/tensile stress (generally <20 MPa). Consequently, most silver pastes are able to accommodate heating and cooling changes by elastically and plastically deforming and excessive stress is not induced in either the metal electrode or the solar cell itself.

Depending on the implemented post plating process, electroplated copper fingers can be under either compressive or tensile stress when the solar cells are interconnected. Both of these stress situations can lead to failure of the adhesive bond between the copper and the solar cell surface which can result in fingers being dislodged from the solar cell surface. More frequently spaced busbar structures can limit the thermal expansion/contraction of the finger segments and in doing so reduce the likelihood of fingers either lifting off the surface or peeling.

The commonly known practice is to use fully metallised contact pads 115 as shown in the example in FIGS. 2A and 2B. The contact pads 115 typically have dimensions of 0.8 to 1.2 mm and can intersect one or more metal fingers depending on the finger spacing used. In FIGS. 2A and 2B, the fingers on the solar cell have a spacing of 0.8 mm, however depending on the solar cell type and design, a different finger spacing can be used. Often, the different finger spacings are used on the front and rear surfaces of bifacial solar cells. The contact pads 115 formed on the solar cell are typically square, rectangular or oval in shape and are usually wider than the interconnection wire to allow tolerance for automated alignment of the interconnection electrical wire to the contact pads 115 during the cell stringing process. The diameter of round interconnection wires can range from 200 to 350 μm in diameter. The width of the contact pads can be larger if interconnection flat ribbons are used, with ribbon width varying from ~0.6 mm to up to 1.5 mm. Typical ribbon thicknesses used in manufacturing are 200-250 μm.

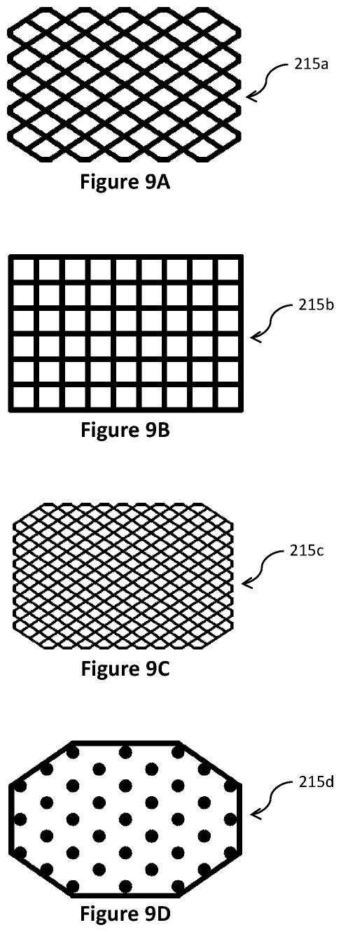

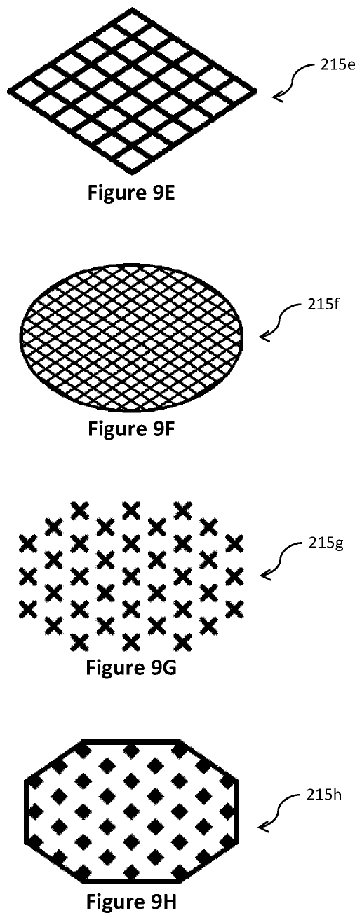

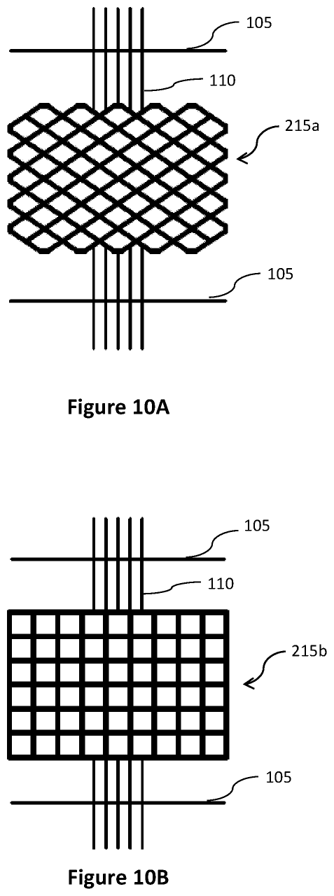

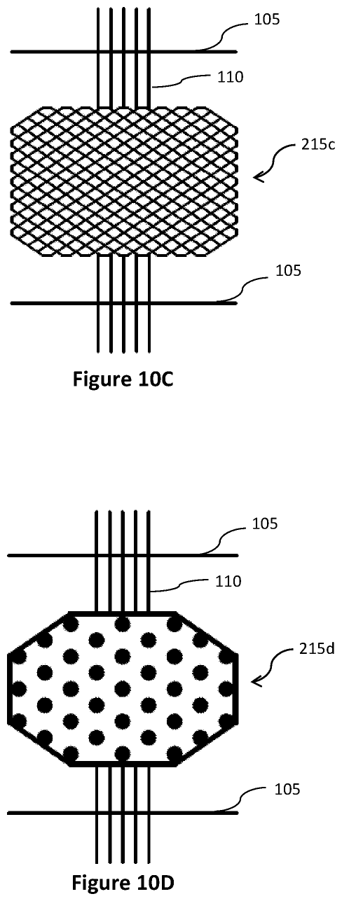

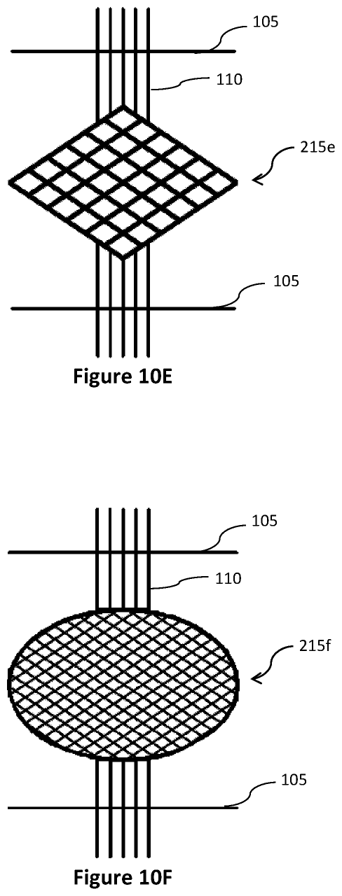

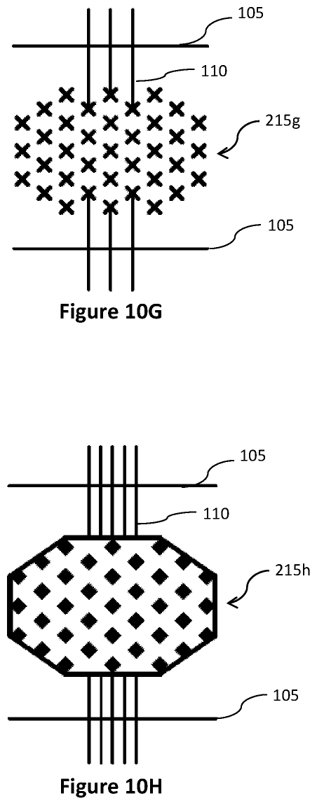

Embodiments of the present invention use patterning, such as high-resolution patterning to replace the fully solid contact pad 115 with a patterned contact pad structure which comprises metallic regions spaced apart by regions at which the solar cell surface is exposed. FIG. 2C shows one of many possible examples of such a patterned contact pad. The metal pattern of the contact pads 215 and the area of contact pads can be varied depending on the properties of the metallisation process (e.g., minimum width). Furthermore, the metallic regions can be spaced apart from the openings in the pattern according to the same or different periods in the two-dimensional pattern. Additional examples of the patterned metal contact will be described further below with reference to FIG. 9 and FIG. 10.

The use of patterned contact pads, such as shown in FIG. 2C is advantageous for a number of reasons. First, when a solder coated interconnection wire coated with a bonding material, such as solder, is brought into contact with a patterned contact pad 215 and heated, the coupling material may flow into the spaces or gaps of the pattern where it proceeds to solidify on cooling. This results in an interlocking solid structure and greater dissipation of the shear stress which is induced in the bonding material when it cools after melting and flowing. Consequently, a more adhesive bond between the interconnection wire and the contact pad forms.

The patterned contact pad, such as shown in FIG. 2C, can reduce the lateral flow of the bonding material from that which would occur with a fully metallised contact pad. With heating, the bonding material flows into the spaces between the metal segments and therefore its lateral spread in the plane of the solar cell is reduced. This can result in a thicker layer of bonding material over a smaller pad area which can further reduce shear stress in the solder close to its interface with the patterned contact pad. Unlike other approaches for reducing lateral flow of a bonding material on a substantially planar surface, the physical properties of the bonding material, the solar cell surface or the metal in an embodiment do not need to be modified.

Further, the patterned contact pad structure can be designed to accommodate stress which is induced in the electroplated copper used to form the contact grid. Accommodation of this stress by allowing metal structures (fingers and contact pads) to expand and contract (with respect to the underlying silicon wafer) can enhance the adhesion of the contact pad regions to the surface of the solar cell as induced stress in the metal can disrupt the adhesion of the metal to the solar cell surface. In an embodiment, this reduction in stress is achieved by using a single metal (e.g., electroplated copper). The term “single metal” or “single material” as used herein is to mean a segment or portion, either partially or wholly, formed or made from a metal or material that is not formed with another metal or material. Put another way, the “single material” may be formed from substantially a single chemical element. For example, when the metallic contact is formed from copper, such as that formed by electrodeposition of copper on a surface, the metallic contact is substantially free from metals other than copper. However, it should be appreciated that the “single metal” or “single material” or “substantially a single chemical element” may include trace amounts of impurities. The single material may also include materials such as screen-printed silver which, in this embodiment, has silver as being the “single material”.

Finally, the amount of copper required to be plated at a contact pad can be reduced. As mentioned above, this can reduce the amount and hence cost of the metal applied to the cell surface. For some solar cell types, where the contact pad metal is in either direct or indirect contact with the solar cell absorber material, the reduced metal area can also reduce potential electrical carrier recombination at the metal interface with the solar cell and, in doing so, increase the energy conversion efficiency of the solar cell.

The above-mentioned advantages of patterned contact pads can be realized if the electrically conductive wire is bonded by thermal or IR radiation (e.g., IR soldering) or if bonding occurs during lamination. The latter process can present some advantages for solar cells, like silicon heterojunction (SHJ) cells, which are sensitive to higher temperatures.

The bonding material can be an alloy, solder or a conductive adhesive. In one embodiment the electrically conductive wire is coated on all surfaces with a metal alloy or solder material. The solder material will form a solder bond between the material of the electrically conductive wire and the patterned metal contact pads of the solar cell and may for example include SnPb solder, or a low melting temperature solder alternative comprising, for example, SnBi, SnBiAg, SnBiln or SnBiPb or may be another suitable type of solder. For solar cells which are sensitive to higher temperatures, low melting temperature solder materials are advantageous. These solder materials are also beneficial in that they can eliminate the use of lead in the resulting PV modules.

Alternatively, the bonding material can be an electrically conductive adhesive comprising an adhesive polymer material with conductive particles. The adhesive polymer can be an epoxy or acylate material and the conductive particles are commonly silver particles or silver-capped copper particles, although other conductive materials can also be used. As explained for the case when solder is the bonding material, when the adhesive material is heated it can flow into the spaces between the metallic segments of the pattern to form an interlocking contact structure. Examples of electrically conductive adhesives are provided by companies such as Henkel, Loctite. Typically, a conductive adhesive is applied only to the surface of the interconnection wire which contacts the solar cell.

A specific embodiment of the present invention will now be described in more detail with reference to n-type silicon heterojunction (SHJ) solar cells, a type of silicon semiconducting solar cell, where doped amorphous (alternatively nano-or micro-crystalline) silicon layers are used to form each of the electron and hole collectors for the solar cell. For bifacially contacted SHJ solar cells, typically the electron contact (also referred to as the n-type contact) is formed on the front surface, whilst the hole contact (also referred to as the p-type contact) is formed on the rear surface of the solar cell. Both solar cell surfaces are coated with a transparent conducting oxide (TCO) which acts as an anti-reflection coating for the solar cell and facilitates lateral current flow to the metal fingers of the contact grid. In alternative cell designs, the hole contact can be formed on the front surface of the solar cell.

The TCO may comprise indium tin oxide (ITO) with In₂O₃:SnO₂ ratios ranging from 90:10 to 97:3 or 99:1. Typically for higher light capture, the front surface of the solar cell will use a higher In₂O₃:SnO₂ ratio to reduce parasitic absorption. Alternatively, the TCO can comprise a range of alternative materials including but not limited to transition metal doped SnO₂, InWO, InCeO, InCsO, InTiO, InTaO and other indium free TCOs such as aluminum doped zinc oxide (AZO). Typically, the TCO thickness is in the range of 60 to 150 nm and such as between 80 and 100 nm. When a SHJ cell is illuminated, electrons are collected in the n-type doped surface silicon layer (typically on the front surface) and then flow into the TCO where they are conducted laterally to reach the nearest metal finger of the contact grid. Similarly, photo-generated holes are collected on the rear p-type silicon layer and flow via the TCO layer into the p-type (rear) contact grid.

The sheet resistance of the TCO is typically between 30 and 110 Ohm/sq, such as between 40 and 80 Ohm/sq. The finger spacing is optimized to minimize electrical losses which can arise from metal shading (resulting in reduced electrical current generation) and lateral resistance to current flow in the TCO layer.

Embodiments of the present invention are not limited by the design of the solar cell (e.g., thickness of the surface contacting layers on the silicon wafer, optimization of the finger spacing) and guidance on how to minimize electrical performance losses of contact grids for solar cells is described in numerous textbooks, including “Solar Cells: Operating Principles Technology (The Red Book)” By M. Green (ISBN: 0858235803).

Embodiments of the present invention can also be applied to other types of silicon-based solar cells, which may be fabricated on either n-type or p-type silicon wafers. In these solar cells, doped silicon regions can form the electron and hole collectors, and the metal contact grids can directly contact the doped silicon regions rather than a TCO. However, the optimization of the contact grid is essentially the same as described here for a SHJ cell.

Copper can be used to form the contact grid on both major surfaces of SHJ solar cells in a number of ways. Copper paste can be screen printed directly on the TCO surface; however, there are a number of disadvantages with this approach. First, the copper particles of these pastes must be capped with silver, and this limits the cost benefits of using copper. Second, the pastes have a higher electrical resistivity than pure copper and so a higher copper loading must be used in order to achieve a desired conductivity. Third, the resolution of screen printing is limited to ~30 μm if reliably continuous thin fingers are to be formed.

Alternatively, a metal layer (e.g., copper) can be sputtered or evaporated over the entire solar cell surface and then patterned into a contact grid having the required geometry. With this approach, care is required to ensure that the removal of the unwanted metal from the TCO surface does not electrically impact the solar cell. To reduce cost, the metal layer (typically copper) can be very thin and act as a seed layer. A masking layer can be formed over the metal layer and a contact grid pattern can be formed in the mask. The openings in the mask can then be exposed to a copper electrolyte whilst the seed layer is electrically contacted. This results in copper being electroplated to the copper seed layer exposed in the mask openings to form a thicker contact grid. Once the contact grid has been thickened by plating copper, the masking material and the seed layer outside of the contact grid is removed resulting in a copper contact grid on the surface of the solar cell. This method is referred to as a “seed layer etchback” method of metallization.

In one specific embodiment the contact grid, comprising fingers 105 and busbar structures 110 with contact pads 115, is electrochemically deposited through a pre-patterned mask directly on the TCO surface. Unlike the above-mentioned prior art method, a seed metal layer is not required.

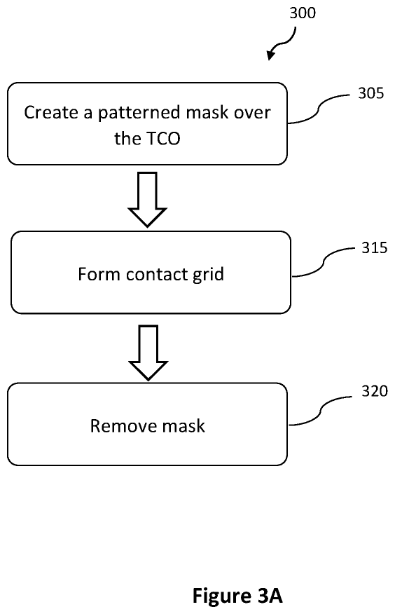

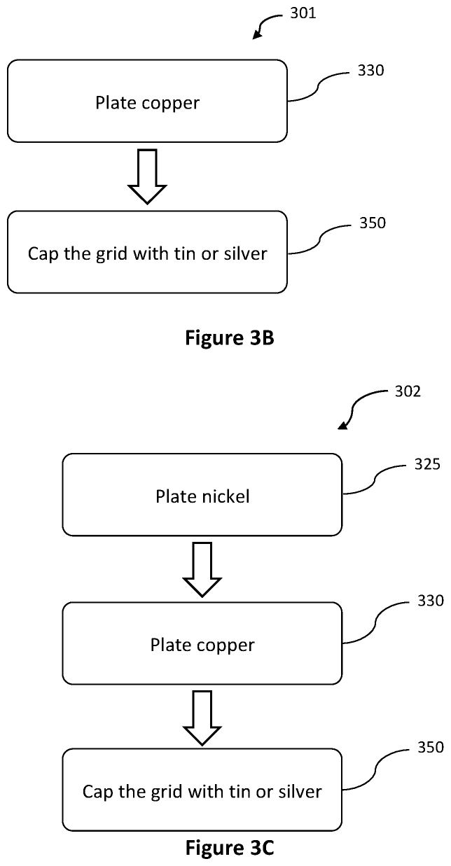

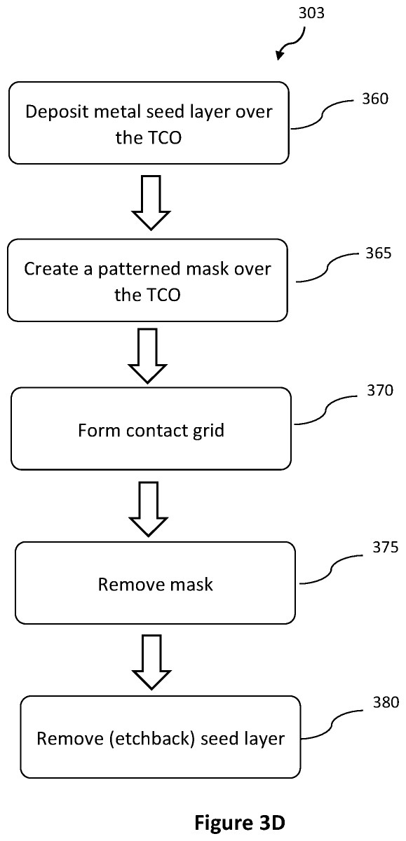

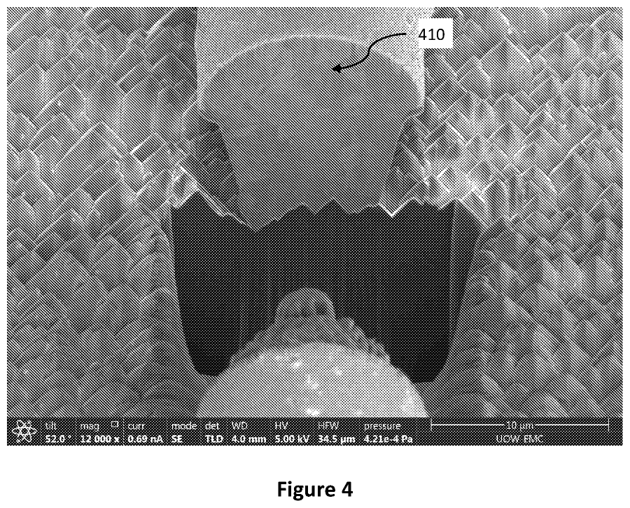

An example of a method for forming a contact grid is now described with reference to FIG. 3A. Using this method, copper fingers having a width as narrow as 10 μm can be achieved (as shown in FIG. 4). These fine feature sizes provide improved control over the mechanism of bond formation between solder and contact pads on the solar cell.

In step 305 of the method 300 a masking layer is formed over the TCO and patterned into openings for the contact grid. The masking layer can comprise an organic resist polymeric material such as a novolac resin and patterning can be achieved using photolithography (which is well known in the field) or using other patterning methods such as inkjet patterning (see for example: Z. Li et al., Patterned masking using polymers: insights and developments from silicon photovoltaics, International Material Reviews, 61:6, 416-435, 2016). Another common masking method comprises the direct printing of a hot melt wax mask. For this method, the wax is melted in the printhead and, when encountering the substrate, the wax solidifies in a mask pattern (see: A. Descoeudres et al., Low-temperature processes for passivation and metallization of high-efficiency crystalline silicon solar cells, Solar Energy, 175, 54, 2018). Alternatively, a thin inorganic mask can be used with patterning being achieved using laser ablation or inkjet removal of the inorganic material in the pattern of the desired metal grid (see T. Hatt et al., Advances with resist-free copper plating approaches for the metallization of silicon heterojunction solar cells, AIP Conference Proceedings 2156, 020010, 2019). In practice any of these masking/patterning methods can be used provided that they can achieve a sufficiently high-resolution mask pattern of segments for a pattern contact pad such as shown in FIG. 2C.

Once the contact grid pattern has been formed in the masking layer, the TCO regions exposed through the mask may be pre-treated in preparation for plating. The pre-treatment ensures that the plated metal (which will be deposited in step 315 of the method 300) will adhere strongly to the TCO surface. This process can for example be an electrochemical wet chemical treatment or a chemical process or a process utilizing a hydrogen plasma. The type of pre-treatment process used can depend on the type of TCO used and the specific embodiment of the present invention does not require a specific pre-treatment process to be used.

In step 315 of the method 300, a contact grid is then plated to the TCO through the openings in the mask. Electrochemical deposition of copper can be achieved on both the n-type and p-type surfaces if equipment can enable direct contact to the TCO layer. Current can then flow through the TCO layer to openings in the mask which are in contact with the plating electrolyte. Alternatively, the contact grid can be electrochemically deposited on the n-type and p-type surfaces using light-induced plating and forward-biased plating, respectively.

Light induced plating uses the light induced current (and voltage) of a solar cell to drive the electrochemical deposition (plating) of metal to a negatively polarized solar cell n-type surface. This process has been described in many publications including: A Lennon et al., Evolution of metal plating for silicon solar cell metallization, Progress in Photovoltaics, 21(7), 1454-1468, 2012.

Forward-biased plating enables electrochemical deposition to p-type surfaces by applying a negative potential to the n-type surface of the solar cell. The negative potential forward biases the p-n junction of the solar cell making the p-type TCO surface cathodic. The forward bias plating of SHJ cells is described by R. Boehme et al., Method of manufacturing electrical contacts of a silicon solar cell structure, PCT international publication number WO2011117797.

Once the contact grid has been formed then the mask may be removed in step 320. The method used to remove the mask depends on the type of masking material. By way of example, if an organic resin is used then the mask can be removed by immersion or spraying of dilute alkaline solution.

FIG. 3B and FIG. 3C illustrate examples of methods for forming the contact grid referred to in step 315 of the method 300. In FIG. 3B illustrates a method 301 in which initially copper is plated to the TCO exposed in the openings in the mask in step 330 to form the main conductor. The amount of copper plated (i.e., finger height) depends on the finger and busbar structure spacing and can be optimized using methods that are well understood by those experienced in the art. Once plated, the copper contact grid is then capped with a thin layer of either silver or tin to prevent oxidation of the copper when the individual solar cells are interconnected in a module. This capping layer can be formed using light-induced or forward-biased plating (i.e., as for the underlying copper), or alternatively using an immersion or displacement process. In the latter case, the mask may alternatively be removed (step 320 of method 300) before the capping layer is formed.

FIG. 3C shows a further variation and illustrates a method 302, in which initially a barrier layer of nickel is plated on the TCO surface exposed by the mask opening in step 325 before the copper contact grid is plated. The nickel layer can provide an additional barrier to copper diffusion into the active layers of the solar cell in situations where the TCO layer does not provide a sufficient barrier. The nickel layer can be plated using either light-induced or forward biased plating as described above (step 315 of method 300).

In the described specific embodiment, the method 300 is performed for each of the n-type and p-type surfaces of the solar cell resulting in a bifacial cell which can be interconnected into a string of solar cells and then encapsulated in a PV module which can accept light from both surfaces. A person skilled in the art will appreciate that the order in which the contact grids are formed may be varied and depends on factors such as the selection of the TCO material and the contact grid pattern.

FIG. 3D shows the process flow or method 303 for a comparative “seed layer etchback” metallization process. In step 360 a seed metal layer, such as copper, is deposited over each of the TCO surfaces of the solar cell, then in step 365 a patterned mask is formed over both solar cell surfaces. The methods for forming the pattern in the mask can be as described for method 300, 301 and 302. A metal (e.g., copper) grid can then formed through the openings in the masking layers in step 370 by contacting an external electrode directly to the metal seed layer on each of the solar cell surfaces and electroplating copper directly to the seed layer metal (as described on page 21, line 10-28). Typically, because the electroplated copper adheres strongly to the exposed seed layer, a pre-treatment step is not required. Then in step 375 the mask is removed and in step 380, the seed metal layer is removed/etched leaving the formed contact grid on the surfaces of both TCO layers.

For each of the n-type and p-type contact grids, irrespective of how they are formed, it is critical that the contact grid adheres strongly to the TCO surface. If the interfacial adhesion is not sufficiently strong, then it is difficult to form a bond via the bonding material to busbar structures for interconnection on the individual solar cells into a string of solar cells. For the case of a solder bond, the thermal energy applied to soften the solder so that it can reflow can disrupt a weak TCO-metal bond and prevent cell interconnection from being achieved.

Strong bonding of the contact grid to the TCO of the solar cell is particularly important when automated equipment is used for cell interconnection as strings of interconnected cells are typically lifted and moved for module layout. Although the use of a series of contact pads (as shown in FIG. 1 and FIG. 2) in place of a fully metallised busbar is advantageous from a solar cell metal usage perspective, it results in a reduced metal cell bonding area. Consequently, the adhesion at the contact pads must be stronger than when fully metallised busbars are used.

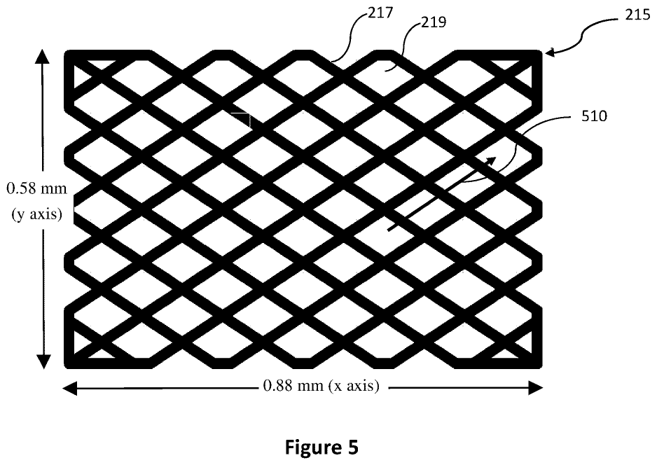

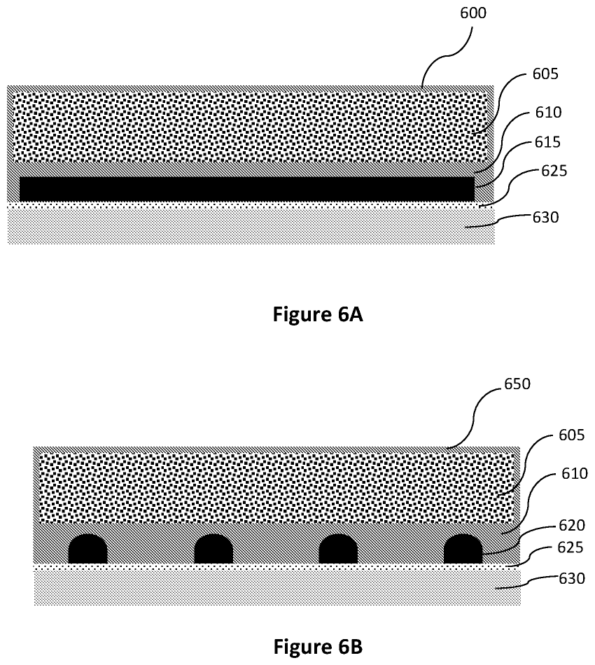

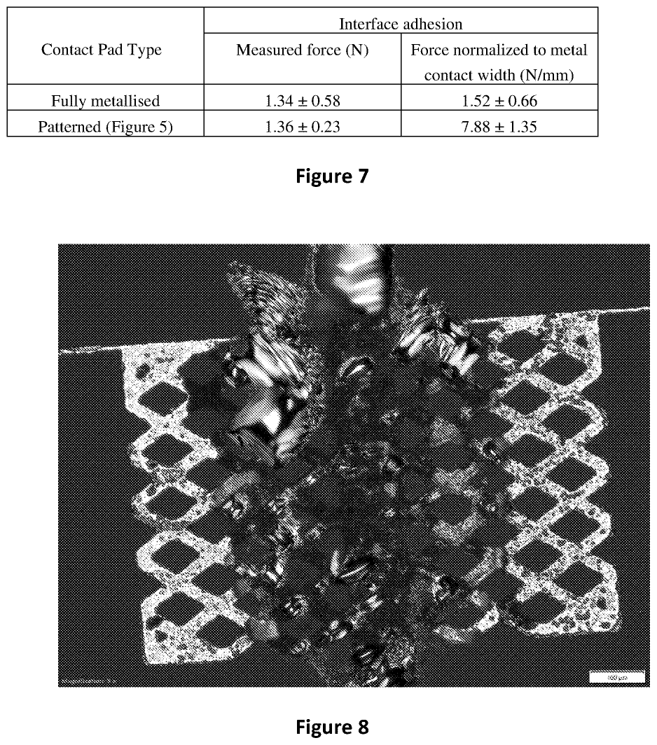

FIG. 5 shows a schematic representation of a region of a patterned contact pad 215. The contact pad 215 has a first regions of metallic material 217 which are spaced apart by second regions 219 in which the substrate is exposed. The first regions 217 are spaced apart by the second regions 219 in two dimensions. In an embodiment, first regions 217 of the metallic material are joined, for example by being integrally formed. In an embodiment, the first regions 217 form a periodic structure. For example, the first regions of the metallic material for a periodic structure. The dimensions of this contact pad are 0.88 mm×0.58 mm, with cross-hatched line segments spaced 0.1 mm along the y axis (height) and 0.15 mm spaced along the x axis. The width of the contact pad 215 is typically determined by the alignment tolerance of an automatic stringing tool. This contact pattern is used for the interconnection of an SHJ solar cell fabricated on an M6 wafer with 12 busbar structures per cell. A pattern of the contact pad 215 may be customized as a function of cell area (i.e., wafer size), number of busbar structures and alignment tolerance of stringing process. Typically, more busbar structures are required as the wafer sizes increases in order to maintain a low metal usage on the solar cell. Stringing equipment with higher interconnection wire alignment can allow for narrower contact pads. The height of the patterned contact pad 215 (i.e., dimension in the direction of the busbar structure) can be increased if greater adhesion of the interconnection wire to solar cell is required. However, it is advantageous to maintain as low a metal usage rate per solar cell in order to reduce cost.

FIG. 6B is a schematic cross-sectional view of an electrical contact 650 including the contact pad 215 also illustrated in FIG. 5 and shows cross-sectional view of linear segment 620 of the linear segments (e.g. the first regions of metallic material 217) of the contact pad 215. The arrow 510 in FIG. 5 shows a direction in which a cross-section shown FIG. 6B is viewed and the plane of the cross-section is perpendicular to the arrow 510. The spacing (gap) between linear segments of the cross-hatched pattern may be between 20 and 100 μm, such as between 30 and 60 μm. The width of the linear segments may for example be between 5 and 20 μm, and more specifically between 5 and 15 μm. In an embodiment, the first regions of the metallic material 217 have a shortest extension in a plane of the metallic contact of less than 100 μm, less than 50 μm, less than 20 μm or even less than 15 μm. In an embodiment, the second regions 219 have a shortest extension in a plane of the metallic contact of less than 500 μm, less than 100 μm, less than 50 μm or even less than 25 μm. In the specific arrangement, the patterned contact pad 215 is formed using the method 300, 301, 302 or 303 described with reference to FIG. 3A, 3B, 3C or 3D respectively.

It is also advantageous that the individual segments of the pattern have a high aspect ratio. However, the greater adhesion, which can result from a more closely spaced cross-hatched or mesh pattern, needs to be balanced against a greater mass of metal required for the contact grid. Ideally, an optimum is obtained between strong adhesion and low metal usage.

FIG. 6B shows the electrical contact 650 with solder bonding material 610 being in direct contact with surface layers 625 of the silicon wafer 630. A person skilled in the art will appreciate that in arrangements in which the linear segments 620 are of a sufficient height and are positioned relatively close together (high aspect ratio of the linear segments 620), the solder material 610 may not flow into the entire spaces between the linear segments 620 such that at least some solder material is then not in direct contact with the surface layers 625. In this case the solder material 610 is positioned over and spaced apart from the surface layers 625.

The plated metal structure, a cross-sectional image of which is shown in FIG. 4, is particularly advantageous. Not only does it have an aspect ratio of ~1:1, the cap region 410 of the plated segments act like a ‘hook’ and helps to lock the solidified solder in place thereby increasing adhesion between electrical wire 605 and the solar cell (the silicon wafer 630 and the surface layers 625) shown in FIG. 6B. Although screen-printing can also be used to form patterned contact pads, it typically results in low aspect ratio metal structures without any ‘interlocking’features such as the above mentioned ‘hook’shown in FIG. 4.

During the cell interconnection process which is commonly referred to as ‘stringing’ when the bonding material is solder, the solar cell with a plurality of busbar structures each comprising a plurality of patterned contact pads 215 is bonded to the electrical wire 605 via the melting and subsequent solidification of the solder material 610. When the solar cell and electrical wire are heated, the solder material 610 flows in between the segments of the cross-hatched pattern of the patterned contact pad 215 and forms an interlocked structure on cooling such as shown in FIG. 6B.

For comparison, FIG. 6A shows a cross-section of an electrical contact 600 for a fully metallised contact pad 615 (prior art). Like components are given like references. In this structure, a single planar solder-metal interface forms on cooling, and there is no interlocking structure to improve adhesion.

In an embodiment, the substrate (e.g. silicon wafer 630) is one of a plurality of substrates which comprise solar cells e.g. within a solar cell module, and the at least one electrically conductive wire is used to interconnect adjacent solar cells within a solar module by connecting one polarity of one of the solar cells with an opposite polarity of an adjacent solar cell.

Strong adhesion of the electrical wire 605 to the solar cell requires that the metal of the contact pads adheres strongly to both the solar cell and the electrical wire 605. In the specific embodiment, described with reference to SHJ solar cells, the metal of the contact pads must adhere strongly to the TCO on the solar cell surface to be contacted. For other types of silicon solar cells, such as passivated emitter rear contact (PERC) cells or thermal oxide passivated contact (TOPCon) cells, strong adhesion is required between the contact pad metal and a silicon surface. For other solar cells, the metal may be in direct contact with other interface materials of the solar cell.

When a material is bonded to another material and heated, shear stress can be induced in the assembly due to the two materials expanding and contracting (on cooling) at different rates. High levels of induced shear stress can result in material fracture and/or disrupted adhesion at the interface between the two materials. Since the copper structures expand and contract more than the silicon wafer, stress is induced in both the copper and the silicon wafer. The intervening solder can plastically deform to reduce the magnitude of the induced stress, however use of a patterned contact pad 215 can further reduce the induced stress because the shorter metal segments of the pattern reduce the physical extent of copper expansion/contraction. Orienting the metal segments of the patterned contact pad 215 in a non-parallel direction can also result in stress being distributed over larger non-metallised areas, thereby reducing the magnitude of any focused stress. In solid metal contact pads, stress in the silicon after cooling is focused at the edges of the contact pads. In an embodiment, a coefficient of thermal expansion of the first region of metallic material (e.g. linear segment 620) is ≥3 times that of the substrate (e.g. silicon wafer 630). The first region of metallic material (e.g. linear segment 620) may have an elastic modulus >50 GPa and/or have a yield stress >25 MPa. In an embodiment, the linear segment 620 is formed from a polycrystalline material. For example, the linear segment 620 may be formed from copper. In an embodiment, the material (e.g. linear segment 620) is or formed from a single material.

Use of a patterned contact pad 215 can also advantageously reduce the spreading or flowing of the solder material 610 during the heating phase. This has the benefit of forming a thicker and hence stronger solder bond over the smaller pad area. The reduced spreading of the solder can reduce even further the shear stress in the solder layer close to the metal segments. The reduced solder flow allows the use of smaller contact pads, which can further reduce the mass of metal required per cell, provided that the electrical wires 605 can be accurately aligned with the typically linear arrangement of contact pads 215 in a busbar structure 110. Use of smaller contact pads can also reduce front surface shading.

Another key advantage of the patterned contact pad 215 is that it can more readily accommodate stress which is induced in the metal of the contact pad and adjacent fingers when the solder cools and solidifies. The CTE of copper is much larger than that of the TCO and silicon. Consequently, when the contact pad is a large solid copper structure (i.e., fully metallised contact pad), the induced shear stress in the copper contact pad on cooling can disrupt the adhesion between the contact pad and TCO resulting in delamination between the contact pad and TCO. Use of patterned contact pads 215 in accordance with embodiments of the present invention reduces the magnitude of the induced shear stress and distributes the vector directions of the stress over the contact pad area thereby reducing the probability of interface failure and consequent delamination of the patterned contact pad from the TCO of the solar cell.

Adhesion of busbar structures to solar cells is routinely measured for solar cells using busbar pull forces. In this measurement, the interconnection wire is pulled from a solar cell, while the solar cell is held fixed on a planar stage. The interconnection wire is oriented at a fixed angle of typically 90° to the plane of the solar cell. Most commonly, the interconnection wire is bonded to the busbar structures by a strong solder bond. Alternatively, the interconnection wire can be bonded to the solar cell using an electrically conductive adhesive material.

For both bonding materials, pulling of the interconnection wire typically disrupts the interface between the solar cell and the busbar structure and the magnitude of the measured force is a measure of how strongly the metal of the busbar structure adheres or bonds to the solar cell surface.

If the bond between the interconnection wire and the metal contact pad on the solar cell is weak (e.g., the adhesive has been incorrectly applied or the solder inadequately melted), then pulling of the interconnection wire can disrupt the bond between the bonding material and the metal of the contact pad. In this situation, the measured force provides little information about the strength of the adhesion between the busbar structure and the solar cell. If the bond between the interconnection wire and the contact pad is stronger than the bond between the solar cell and the metal contact pad, then the metal of the contact pads is typically pulled from the solar cell surface. In this case the measured busbar pulling force is assumed to be a measure of the adhesive strength of the metal (used to form the contact grid) to the solar cell surface.

Another possible outcome of this adhesion measurement can occur if very strong bonds exist between both: (i) the solar cell and the metal of the contact pads (of the one or more busbar structures); and (ii) between the contact pads and the interconnection wire. In this situation, the solar cell material (e.g., the silicon wafer) itself can be fractured resulting in fragments of a wafer being broken from the solar cell as the interconnection wire is pulled.

When fully metallised busbar structures are used, the measured pull force is usually averaged over the length of the busbar structure and normalized to the width of the busbar, the latter normalization is typically employed to take into account the area over which the metal of the busbar structure adheres to the solar cell. Force measurements are therefore represented using units of N/mm. When busbar structures comprise a series of discrete and separate contact pads, it is more common to measure a peak pull force for each contact pad and then average this peak force over all the contact pads on the solar cell. As described for the fully metallised busbar structures, this average peak force can also be normalized by the width of the contact pads to provide measurements (i.e., N/mm).

For the described specific embodiment of the present invention, the metal area of the contact pads is reduced compared to that of fully metallised contact pads. Furthermore, depending on the pattern used for the patterned contact pad, the effective metal contact width may vary in the ‘pulling’ direction. Consequently, the adhesion of contact pads is more appropriately represented by the peak measured force (for the contact pad) divided by the average effective width of the metal patterns of the patterned contact pads. The units of this metric remain N/mm and can be directly compared with measurements from fully metallised contact pads. For example, the average effective metal width of the contact pad shown in FIG. 5 is just 0.17 mm (assuming a metal structure width of 12 μm). This effective width is ~20% of the contact pad width of 0.88 mm for the fully metallised contact pad.

The table shown in FIG. 7 lists average ‘as measured’ and normalized peak busbar pull forces for fully metallised contact pads and contact pads 215 having the pattern schematically illustrated in FIG. 5 formed on SHJ solar cells using the described method in accordance with a specific embodiment of the present invention. The values in the table represent the means and standard deviations of peak forces measured for five consecutive contact pads in copper plated busbar structures. The patterned contact pads 215 result in an average normalised peak force which is ~five times larger than for fully metallised contact pads. The standard deviation in the measured forces is also considerably reduced for the patterned contact pads suggesting that more uniform adhesion of interconnection wire to solar cells can be achieved with patterned contact pads.

In addition, for many patterned contact pads 215, the interfacial adhesion at the contact pad/TCO interfaces is so strong that the pull force measurement results in the silicon wafer cracking and/or fragments of silicon being pulled from the wafer. This demonstrates the exceptionally strong interface adhesion which can be achieved through the patterning of the contact pads. FIG. 8 shows an example of an area on a solar cell with a contact pad having the pattern schematically indicated in FIG. 5 where the busbar pull force has resulted in a fragment of silicon being broken from the entire thickness of the silicon wafer illustrating the strength of the adhesion of the contact to the silicon surface. For solar cells comprising different photovoltaic materials, other failure mechanisms may occur due to the strong interface adhesion between the contact pad metal and the solar cell, such as delamination of the solar cell from a substrate.

The pattern employed for the patterned contact pads 215 can be tuned for specific adhesion properties. Whilst the greatest gain in adhesion is achieved with high resolution cell metallization patterning and high aspect ratio conductive metal structures as described above, some benefits can also be realized with other patterns, contact pad shapes and other metallization methods.

FIG. 9 shows a number of variations of the patterned contact pad shown in FIG. 5. FIG. 9A to FIG. 9C, FIG. 9E and FIG. 9F show, respectively, contact pad patterns 215a, 215b, 215c, 215e, 215f with connected linear metal segments aligned along two principal axes and different perimeter shapes. On heating, the bonding material flows into the regions between the metal segments. FIGS. 9D, 9G and 9H show, respectively, representative examples of contact pad patterns 215d, 215g and 215h where the metal segments are not connected. In these variations, the bonding material flows to electrically connect the metal segments and enhance the redundancy of the electrical current collection. These non-connecting metal variations can be advantageous in that they allow the stress in the underlying silicon to be distributed around the entire perimeter of the metal circle (215g, FIG. 9D), cross (215g, FIG. 9G) and cube (215h, FIG. 9H).

FIG. 10A to FIG. 10H show the patterned contact pads depicted in FIG. 9A to FIG. 9H in association with various busbar 110 structure arrangements and two exemplar metal fingers 105, which are oriented perpendicular to the busbar. As mentioned earlier, the busbars between the contact pads can comprise a series of thinner lines of different spacing.

Although a single metal line can be used to collect current from the metal fingers, use of multiple lines is preferred as it provides greater redundancy in current collection.

It should be clear to those skilled in the art, that numerous possible contact pad designs can be used as embodiments of this invention. It is not necessary for all the metal segments of the contact pad patterns to be connected in the metal pattern because once the bond with the interconnection wire has been formed electrical current can flow from the solar cell into an isolated metal segment of the pattern and then be transferred to the interconnection wire via the solder. However, contact pad patterns which have isolated metal segments can introduce difficulties when measuring the efficiency of the solar cell before cell interconnection.

Throughout this specification the term “comprise”, or variations such as “comprises” or “comprising”, will be understood to imply the inclusion of a stated element, integer or step, or group of elements, integers or steps, but not the exclusion of any other element, integer or step, or group of elements, integers or steps.

Any discussion of documents, acts, materials, devices, articles or the like which has been included in the present specification is not to be taken as an admission that any or all of these matters form part of the prior art base or were common general knowledge in the field relevant to the present invention as it existed before the priority date of each claim of this application.

1-34. (canceled)

35. A method of forming an electrical connection on a surface of a substrate that forms a part of a solar cell, the method comprising:
providing the substrate and a material for forming at least one metallic contact on the surface of the substrate;
forming the at least one metallic contact on the surface of the substrate, comprising selecting at least one contact area on the surface of the substrate and forming a structure of a polycrystalline metallic material within the at least one contact area, the structure having first regions of a polycrystalline metallic material which are spaced apart by second regions in which the substrate is exposed, wherein the first regions are spaced apart by the second regions in two dimensions;
providing at least one electrically conductive wire and a coupling material; and
coupling the at least one electrically conductive wire to the formed at least one metallic contact using the coupling material in a manner such that at least some of the coupling material is also positioned over the substrate at the second regions within the at least one contact area.

36. The method of claim 35 wherein some of the coupling material is positioned over, and spaced apart from the substrate at at least some of the second regions and is not in direct contact with the substrate at each second region.

37. The method of claim 35 wherein the coupling material is a solder material and coupling the at least one electrically conductive wire to the formed at least one polycrystalline metallic contact comprises soldering the at least one electrically conductive wire to the formed at least one polycrystalline metallic contact.

38. The method of claim 35 wherein the coupling material is a conductive adhesive material and coupling the at least one electrically conductive wire to the formed at least one polycrystalline metallic contact comprises adhering the at least one electrically conductive wire to the formed at least one polycrystalline metallic contact.

39. The method of claim 35 wherein the metallic contact comprises at least some first regions of the polycrystalline metallic material which are separate from each other and are not in direct contact with other first regions of the metallic material.

40. The method of claim 35 wherein the at least one metallic contact has a shortest extension in a plane of the metallic contact of less than 2 mm.

41. The method of claim 35 wherein the first regions of the polycrystalline metallic material have a shortest extension in a plane of the metallic contact of less than 100 μm.

42. The method of claim 35 wherein the second regions have a shortest extension in a plane of the metallic contact of less than 500 μm.

43. The method of claim 35 wherein the at least one electrically conductive wire is coated with a solder material.

44. The method of claim 35 further comprising providing a solder material separate from the at least one electrically conductive wire and soldering the at least one electrically conductive wire to the formed metallic contact using the solder material.

45. The method of claim 35 wherein the metallic material comprises at least one of Cu, Ni, Sn and Ag or a combination thereof.

46. The method of claim 35 wherein the at least one metallic contact is one of a plurality of metallic contacts being formed from a polycrystalline metallic material and the method comprises forming a plurality of the metallic contacts on the surface of the substrate.

47. The method of claim 35 wherein the substrate is one of a plurality of substrates which comprise solar cells and wherein the at least one electrically conductive wire is used to interconnect adjacent solar cells by connecting one polarity of one of the solar cells with an opposite polarity of an adjacent solar cell.

48. A device comprising:
a substrate that forms a part of a solar cell;
at least one metallic contact within a contact area, the at least one metallic contact comprising a structure having first regions of a polycrystalline metallic material which are spaced apart by second regions in which the polycrystalline metallic material is not positioned, wherein the first regions are spaced apart by the second regions in two dimensions; and
at least one electrically conductive wire coupled to the polycrystalline metallic material with a coupling material;
wherein at least some of the coupling material is also positioned over the substrate at the second regions within the at least one metal contact area within the contact area.

49. The device of claim 48 wherein some of the coupling material is in direct contact with the substrate in at least some of the second regions.

50. The device of claim 48 wherein some coupling material is positioned over and spaced apart from the substrate at at least some of the second regions without coupling material being in direct contact with the substrate at each second region.

51. The device of claim 48 wherein the at least one metallic contact has a shortest extension in a plane of the metallic contact of less than 2 mm.

52. The device of claim 48 wherein the first regions of the metallic contact have a shortest extension in a plane of the at least one metallic contact of less than 100 μm.

53. The device of claim 48 wherein the second regions of the metallic contact have a shortest extension in a plane of the at least one metallic contact of less than 500 μm.

54. The device of claim 48 wherein the device comprises a solar cell and wherein the coupling material is an electrically conductive adhesive.
